(19) United States
(12) Patent Application Publication
(10) Pub. No.: US 2017/0262042 A1
(43) Pub. Date: Sep. 14, 2017

(54) INFORMATION PROCESSING APPARATUS AND SWITCHING CONTROL METHOD

(71) Applicant: FUJITSU LIMITED, Kawasaki-shi (JP)

(72) Inventor: Kenichi KAWASAKI, Kawasaki (JP)

(73) Assignee: FUJITSU LIMITED, Kawasaki-shi (JP)

(21) Appl. No.: 15/429,572

(22) Filed: Feb. 10, 2017

(30) Foreign Application Priority Data
Mar. 10, 2016 (JP) 2016-047620

(51) Int. Cl. G06F 1/32; G11C 5/14

(52) U.S. Cl. CPC G06F 1/3287; G11C 5/148; G06F 1/3206

(57) ABSTRACT

An information processing apparatus includes a volatile memory, a nonvolatile memory, and a processor coupled to the volatile memory and the nonvolatile memory, the processor configured to make a selection of the volatile memory or the nonvolatile memory to be supplied power, based on a first difference between power consumption of the volatile memory and power consumption of the nonvolatile memory during standby, and a second difference between power consumption of the volatile memory and power consumption of the nonvolatile memory during an operation state, and switch between the volatile memory and the nonvolatile memory to be supplied power on the basis of the selection and whether the volatile memory or the nonvolatile memory being used currently by the processor.

### CROSS-REFERENCE TO RELATED APPLICATION

This application is based upon and claims the benefit of priority of the prior Japanese Patent Application No. 2016-047620, filed on Mar. 10, 2016, the entire contents of which are incorporated herein by reference.

### FIELD

The embodiments discussed herein are related to an information processing apparatus and a switching control method.

### BACKGROUND

In an information processing apparatus represented by a smartphone, a wearable device, and the like, it is important to suppress the power consumption by a memory, serving as a component, in order to suppress the standby power consumption. Currently, a volatile memory, such as a dynamic random access memory (DRAM), is mainly used as a main memory. While a DRAM is high speed and inexpensive, the standby power consumption for retaining data is high.

FIG. 16 is a diagram for explaining the power consumption of an information processing apparatus using a DRAM. As illustrated in FIG. 16, in the information processing apparatus in which an operation state and a standby state are alternated, the power to the DRAM may not be turned off even in a standby state, since a DRAM is a volatile memory and data is lost when the power is turned off. Accordingly, the power consumption of the information processing apparatus in the standby state (the standby power consumption) is high compared with the case in which the power to the DRAM may be turned off.

Thus, a nonvolatile memory, such as a magneto resistive random access memory (MRAM), or the like, may conceivably be used as a main memory in place of a DRAM. However, in the case of an MRAM, power consumption during operation is higher than that of the DRAM. FIG. 17 is a diagram for explaining the power consumption of an information processing apparatus using an MRAM. As illustrated in FIG. 17, the standby power consumption of an MRAM is lower than a DRAM, since the power to an MRAM in the standby state may be turned off.

However, since the current consumption of an MRAM is high in the operation state, the power consumption of an MRAM during operation (the operating power consumption) is higher than a DRAM. Accordingly, while simply replacing a DRAM with an MRAM may yield a power consumption reduction effect illustrated by (1) in some cases, but may conversely increase the power consumption due to the increase in the operation power consumption illustrated by (2).

For this reason, there is a technique in which, a nonvolatile memory is provided in addition to a volatile memory such as a DRAM, memory access requests are monitored, and a determination is accordingly made as to which of the volatile memory or the nonvolatile memory is operated as the main memory, based on the monitoring result.

Also, there is a technique that enables reduction in the power consumption of a mobile device by providing the mobile device with a control unit that controls the power supply to a memory unit that has to be refreshed and to an external memory unit that is capable of storing and retaining data without depending on the power supply.

### CITATION LIST

### Patent Documents

Related-art techniques are disclosed in Japanese Laid-open Patent Publication Nos. 2014-232525 and 2004-199339.

### SUMMARY

According to an aspect of the invention, an information processing apparatus includes a volatile memory, a nonvolatile memory, and a processor coupled to the volatile memory and the nonvolatile memory, the processor configured to make a selection of the volatile memory or the nonvolatile memory to be supplied power, based on a first difference between power consumption of the volatile memory and power consumption of the nonvolatile memory during standby, and a second difference between power consumption of the volatile memory and power consumption of the nonvolatile memory during an operation state, and switch between the volatile memory and the nonvolatile memory to be supplied power on the basis of the selection and whether the volatile memory or the nonvolatile memory being used currently by the processor.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a smartphone according to a first embodiment;

FIG. 2 is a diagram for explaining switching between a DRAM and an MRAM;

FIG. 3 is a diagram for explaining a switching criterion between a DRAM and an MRAM;

FIG. 4 is a diagram illustrating a functional configuration of a switching control unit;

FIG. 5 is a diagram illustrating an example of an allocation information storage unit;

FIG. 6 is a diagram illustrating items stored in a mode determination information storage unit;

FIG. 7A is a diagram (one memory area) for explaining turning on and off the power to memories;

FIG. 7B is a diagram (four memory areas) for explaining turning on and off the power to memories;

FIG. 8 is a flowchart illustrating a processing flow by the switching control unit;

FIG. 9A is a diagram illustrating an example of switching operation (DRAM→MRAM);

FIG. 9B is a diagram illustrating an example of switching operation (MRAM→DRAM);

FIG. 10 is a diagram illustrating advantages of switching control according to the first embodiment;

FIG. 11 is a diagram for explaining the case in which CT fluctuates in the vicinity of X;

FIG. 12 is a flowchart illustrating a processing flow by the switching control unit according to a second embodiment;

FIG. 13 is a diagram illustrating an example of switching operation according to a second embodiment;

FIG. 14 is a diagram for explaining switching control by a hysteresis determination method;

FIG. 15 is a flowchart illustrating a processing flow by a switching control unit according to a third embodiment;

FIG. 16 is a diagram for explaining the power consumption of an information processing apparatus using a DRAM; and

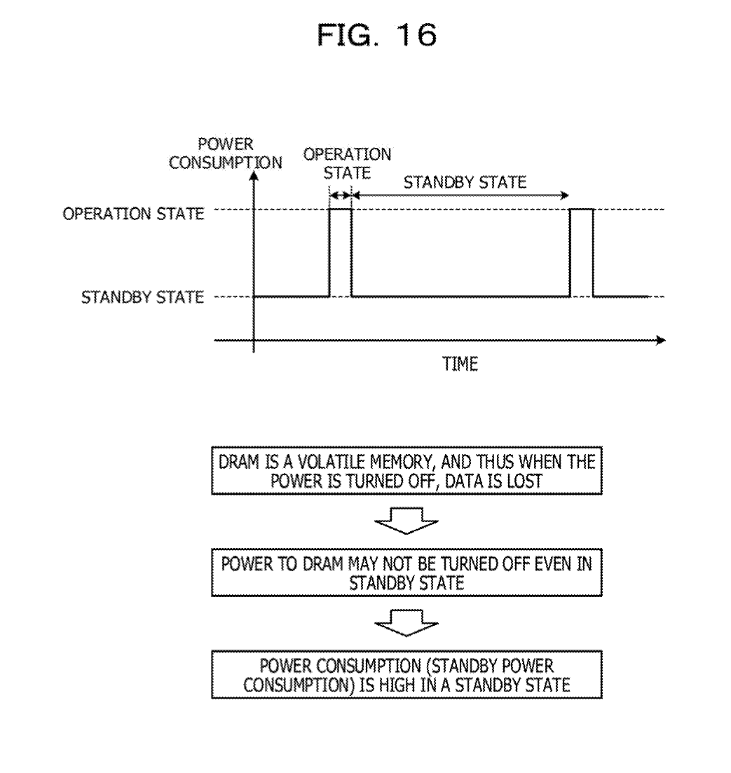

FIG. 17 is a diagram for explaining the power consumption of an information processing apparatus using an MRAM.

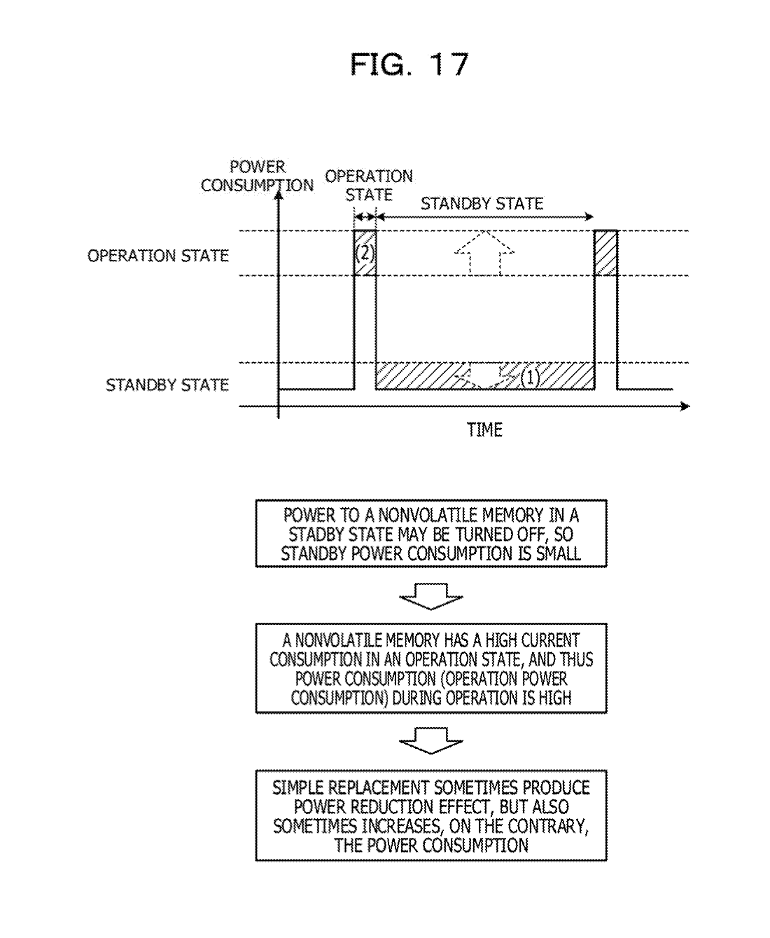

### DESCRIPTION OF EMBODIMENTS

When a volatile memory and a nonvolatile memory are used as a main memory, which memory is better used for lowering the power consumption differs depending on the operation state of an information processing apparatus. Accordingly, switching between the volatile memory and the nonvolatile memory to lower the power consumption according to the operation state of the information processing apparatus becomes an issue.

In the following, a detailed description will be given of an information processing apparatus, a switching control method, and a switching control program according to embodiments of the present disclosure with reference to the drawings. In this regard, the embodiments will not limit the disclosed technique.

### First Embodiment

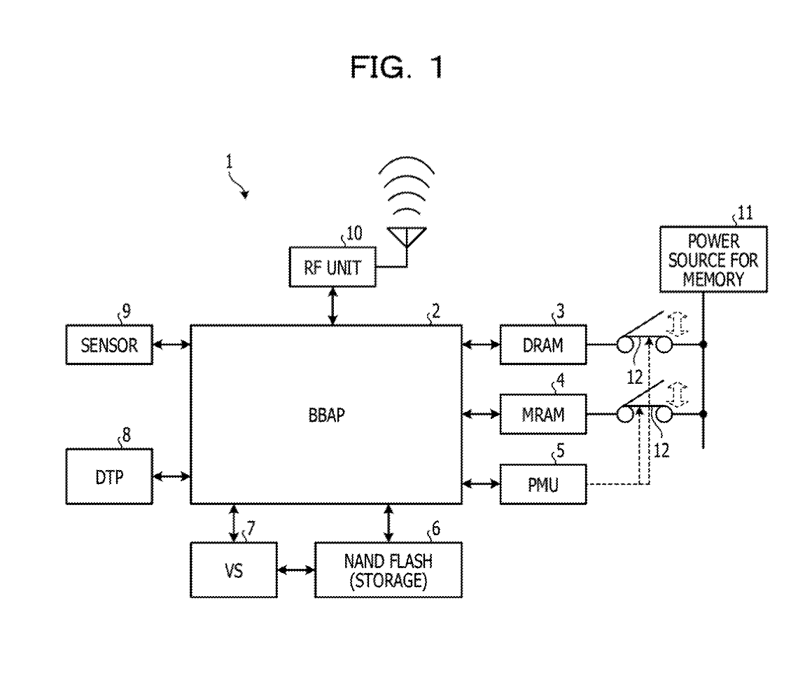

First, a description will be given of a configuration of a smartphone according to a first embodiment. FIG. 1 is a diagram illustrating a configuration of a smartphone according to the first embodiment. As illustrated in FIG. 1, a smartphone 1 includes a baseband & application processor (BBAP) 2, a DRAM 3, an MRAM 4, a power management unit (PMU) 5, a NAND flash 6, and a voice & speaker (VS) 7. Also, the smartphone 1 includes a display & touch panel (DTP) 8, a sensor 9, a radio frequency (RF) unit 10, a memory power source 11, and a switch 12.

The BBAP 2 is a processor for baseband and applications, and is an arithmetic processing unit that performs communication processing, information processing, and the like. The DRAM 3 is a volatile memory and stores programs to be executed by the BBAP 2, intermediate results of the execution, and the like. The MRAM 4 is a nonvolatile memory and stores programs to be executed by the BBAP 2, intermediate results of the execution, and the like in the same manner as the DRAM 3. The DRAM 3 and the MRAM 4 operate as the main memory and are used being switched by the BBAP 2.

The PMU 5 opens and closes the switch 12 based on an instruction from the BBAP 2 so as to perform on-off control of the DRAM 3 and the MRAM 4. The NAND flash 6 is a nonvolatile memory that stores programs and data. The programs stored in the NAND flash 6 are read into the DRAM 3 or the MRAM 4 and are executed by the BBAP 2.

The VS 7 is a device that inputs and outputs sound. The DTP 8 is a display device that displays a screen and includes a touch panel that accepts a user's operation on the screen. The sensor 9 is a device that measures temperature, and the like. The RF unit 10 is a module that performs wireless communication with a base station. The memory power source 11 is a device that supplies power to the memories. The switch 12 turns on and off the power to the DRAM 3 or the MRAM 4 under the control of the PMU 5.

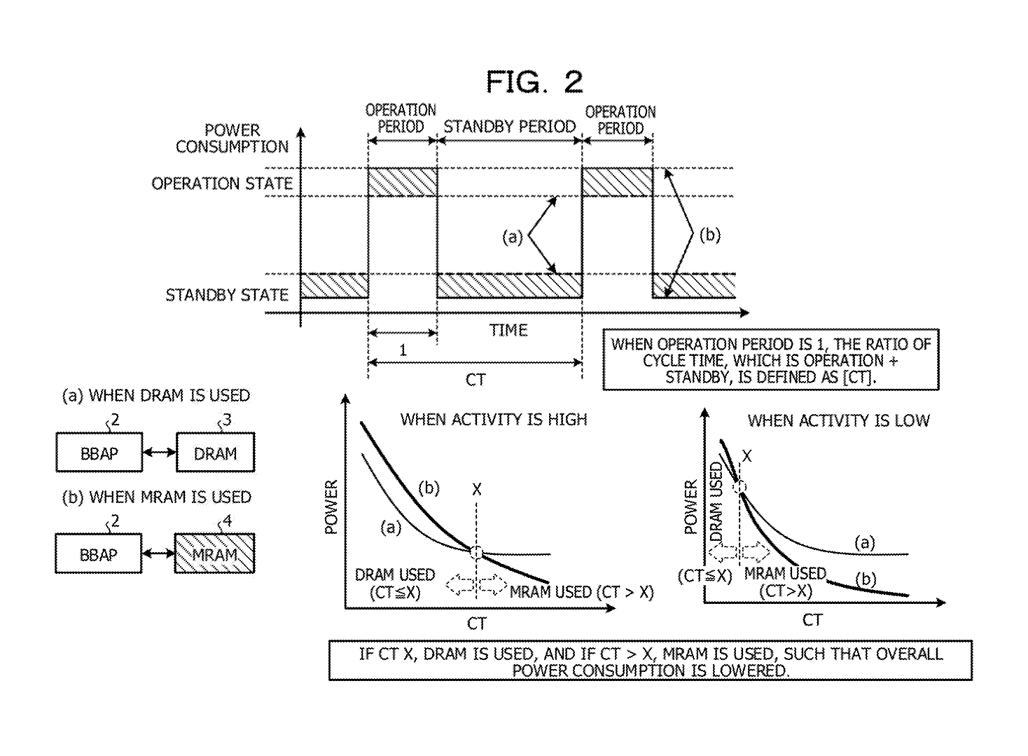

Next, a description will be given of switching between the DRAM 3 and the MRAM 4. FIG. 2 is a diagram for explaining switching between the DRAM 3 and the MRAM 4. In FIG. 2, (a) illustrates the case in which the DRAM 3 is used as the main memory, and (b) illustrates the case in which the MRAM 4 is used as the main memory. When the DRAM 3 is used, the operation power consumption is low and the standby power consumption is high compared with the case in which the MRAM 4 is used. On the contrary, when the MRAM 4 is used, the operation power consumption is high and the standby power consumption is low compared with the case in which the DRAM 3 is used.

As illustrated in FIG. 2, when an operation period is 1, it is assumed that the ratio of a cycle time is CT. Here, the cycle time is the operation period+the standby period. When the power consumption (illustrated by “Power” in FIG. 2) of the smartphone 1 with respect to CT is graphically illustrated for the DRAM 3 (a) and the MRAM 4 (b), respectively, there is a point X where the two lines intersects in each of the two graphs.

In FIG. 2, the graphs are illustrated separately in the case in which activity is high and the case in which activity is low. Here, the activity is the access frequency from the BBAP 2 to the main memory, and is represented by the operation rate of the main memory. In both of the graphs, when CT is smaller than X, the power consumption in the case (a) is lower than the power consumption in the case (b), and when CT is larger than X, the power consumption in the case (a) is higher than the power consumption in the case (b).

The reason for this is because as CT becomes larger, the standby period becomes longer compared with the operation period, and thus the power consumption becomes lower in the case in which the MRAM 4 is used. Accordingly, this enables power consumption of the smartphone 1 to be lowered by using the DRAM 3 when CT≦X, and using the MRAM 4 when CT>X.

Further, the value of X is larger when the activity is high, compared with the case in which the activity is low. The reason for this is that when the activity is high, there are many accesses to the main memory, making the operation power consumption high. Thus, in order to make the amount of increase in operation energy equal to the amount of decrease in standby energy, the standby period becomes longer.

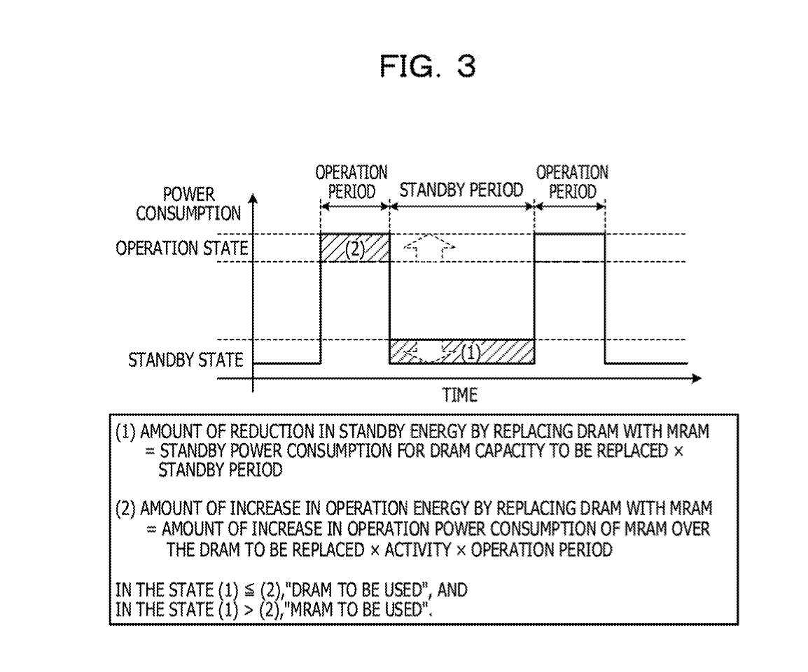

FIG. 3 is a diagram for explaining a switching criterion between the DRAM 3 and the MRAM 4. As illustrated in FIG. 3, the amount of reduction in the standby energy (1) by replacing the DRAM 3 with the MRAM 4 is the standby power consumption for the DRAM capacity to be replaced×the standby period. Also, the amount of increase in operation energy (2) by replacing the DRAM 3 with the MRAM 4 is the amount of increase in the operation power consumption of the MRAM 4 with respect to the DRAM 3 to be replaced×the activity×the operation period.

Thus, smartphone 1 uses the DRAM 3 in the state in which (1)≦(2), and uses the MRAM 4 in the state in which (1)>(2). Namely, X is the value of CT when (1)=(2).

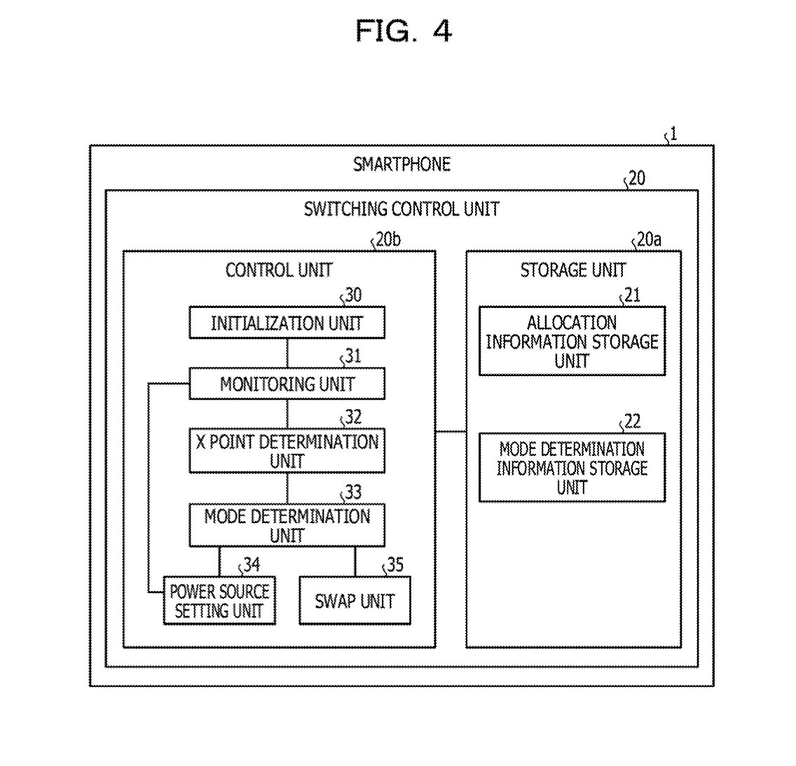

Next, a description will be given of the functional configuration of a switching control unit that switches between the DRAM 3 and the MRAM 4. FIG. 4 is a diagram illustrating the functional configuration of the switching control unit. As illustrated in FIG. 4, the switching control unit 20 includes a storage unit 20a that stores the information used for switching control and a control unit 20b that controls switching using the information stored in the storage unit 20a.

The storage unit 20a includes an allocation information storage unit 21 and a mode determination information storage unit 22. The control unit 20b includes an initialization unit 30, a monitoring unit 31, an X-point determination unit 32, a mode determination unit 33, a power source setting unit 34, and a swap unit 35. The control unit 20b is a processor, for example a central processing unit (CPU), or the like.

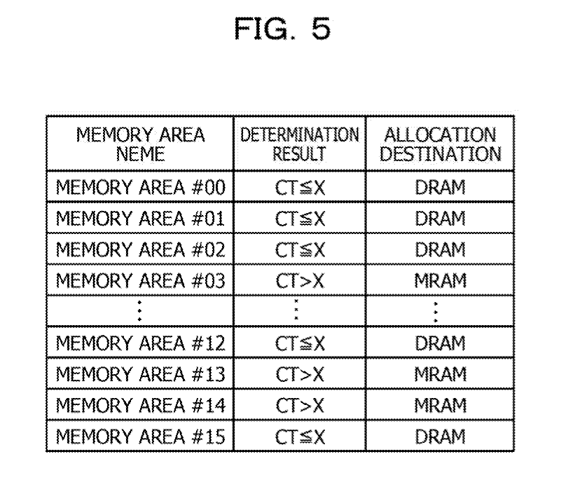

The allocation information storage unit 21 stores information regarding the allocation of the main memory to the DRAM 3 or the MRAM 4. FIG. 5 is a diagram illustrating an example of the allocation information storage unit 21. As illustrated in FIG. 5, the allocation information storage unit 21 stores a memory area name, a determination result, and an allocation destination for each memory area.

The memory area name is a name for identifying each memory area of the main memory. The determination result indicates a result of the determination as to which of the DRAM 3 or the MRAM 4 is better used for the memory area in order to lower the power consumption. “CT≦X” represents a determination result stating that the DRAM 3 is better used, and “CT>X” represents a determination result stating that the MRAM 4 is better used.

The allocation destination indicates whether the DRAM 3 is allocated to the memory area or the MRAM 4 is allocated to the memory area. “DRAM” represents that the DRAM 3 is allocated, and “MRAM” represents that the MRAM 4 is allocated. For example, in the memory area identified by “memory area #00”, it is determined that the DRAM 3 is better used, and thus the DRAM 3 is allocated.

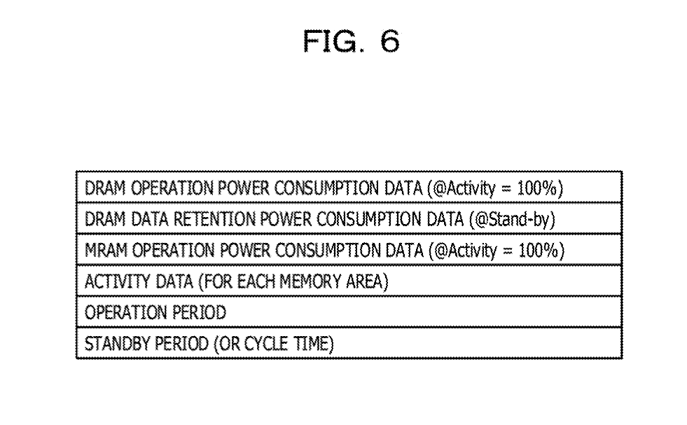

The mode determination information storage unit 22 stores information for determining which of the DRAM use mode in which the DRAM 3 is used for the main memory or the MRAM use mode in which the MRAM 4 is used for the main memory is selected. FIG. 6 is a diagram illustrating items stored in the mode determination information storage unit 22. As illustrated in FIG. 6, the mode determination information storage unit 22 stores DRAM operation power consumption data, DRAM data retention power consumption data, MRAM operation power consumption data, activity data, operation period, and standby period.

The DRAM operation power consumption data represents the operation power consumption of the DRAM 3. “@Activity=100%” indicates that the data is for the case in which the activity is 100%. The DRAM data retention power consumption data represents the power consumed for retaining data in the DRAM 3. “@Stand-by” indicates that the data is for the state in which the DRAM 3 is not operating.

The MRAM operation power consumption data represents the operation power consumption of the MRAM 4. The activity data represents the activity of the main memory. The activity data is data for each memory area. The operation period is the operation period of the smartphone 1. The standby period is the standby period of the smartphone 1. The mode determination information storage unit 22 may store the cycle time in place of the standby period.

The DRAM operation power consumption data, the DRAM data retention power consumption data, and the MRAM operation power consumption data are values that are obtained from the data sheets or values obtained by measurement and are fixed values. The activity data, the operation period, and the standby period are values obtained by monitoring the smartphone 1 and are variable values.

The initialization unit 30 performs initialization for switching control when the smartphone 1 is started. Specifically, the initialization unit 30 initializes the determination result and the allocation destination in the allocation information storage unit 21 to the DRAM use mode, and performs the initial setting of the activity data, the operation period, and the standby period in the mode determination information storage unit 22.

When the smartphone 1 is in the operation state, the monitoring unit 31 monitors CT and the activity, and writes the monitoring result in the mode determination information storage unit 22. The monitoring unit 31 monitors CT by monitoring the operation period and the standby period of the smartphone 1.

The X-point determination unit 32 performs X-point determination when the smartphone 1 is in the operation state. Here, the X-point determination represents comparing CT and X to determine if CT≦X or CT>X. CT is calculated from the operation period and the standby period of the smartphone 1.

As illustrated in FIG. 3, X is calculated as a value of CT when the standby power consumption of the capacity of the DRAM to be replaced×the standby period=the increase in operation power consumption with the MRAM 4×the activity×the operation period. The standby power consumption of the capacity of the DRAM to be replaced represents the DRAM data retention power consumption data stored in the mode determination information storage unit 22. The increase in the operation power consumption with the MRAM 4 is calculated from the DRAM operation power consumption data and the MRAM operation power consumption data that are stored in the mode determination information storage unit 22. In this regard, the value of X may be calculated in advance for the activity in a certain range, such as 10% to 50%.

The mode determination unit 33 determines whether or not the currently used mode matches the determined mode when the smartphone 1 changes from the operation state to the standby state. Here, the currently used mode represents the memory currently allocated as the memory area, and is either the DRAM use mode or the MRAM use mode. The determined mode is the memory use mode based on the determination result by the X-point determination unit 32, and is either the DRAM use mode or the MRAM use mode.

If the currently used mode dose not match the determined mode, the mode determination unit 33 instructs the power source setting unit 34 and the swap unit 35 to perform memory switching processing. In this regard, the processing of the X-point determination unit 32 and the mode determination unit 33 is performed for each memory area.

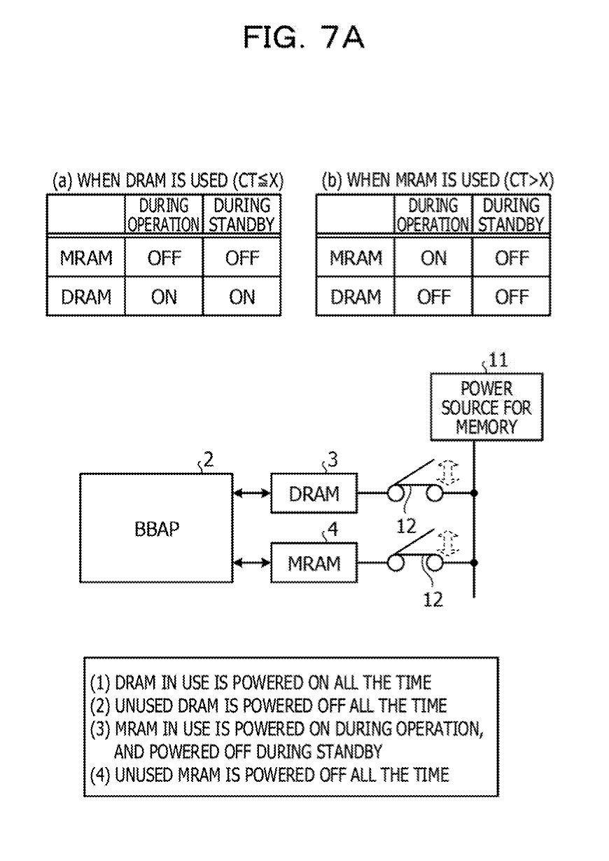

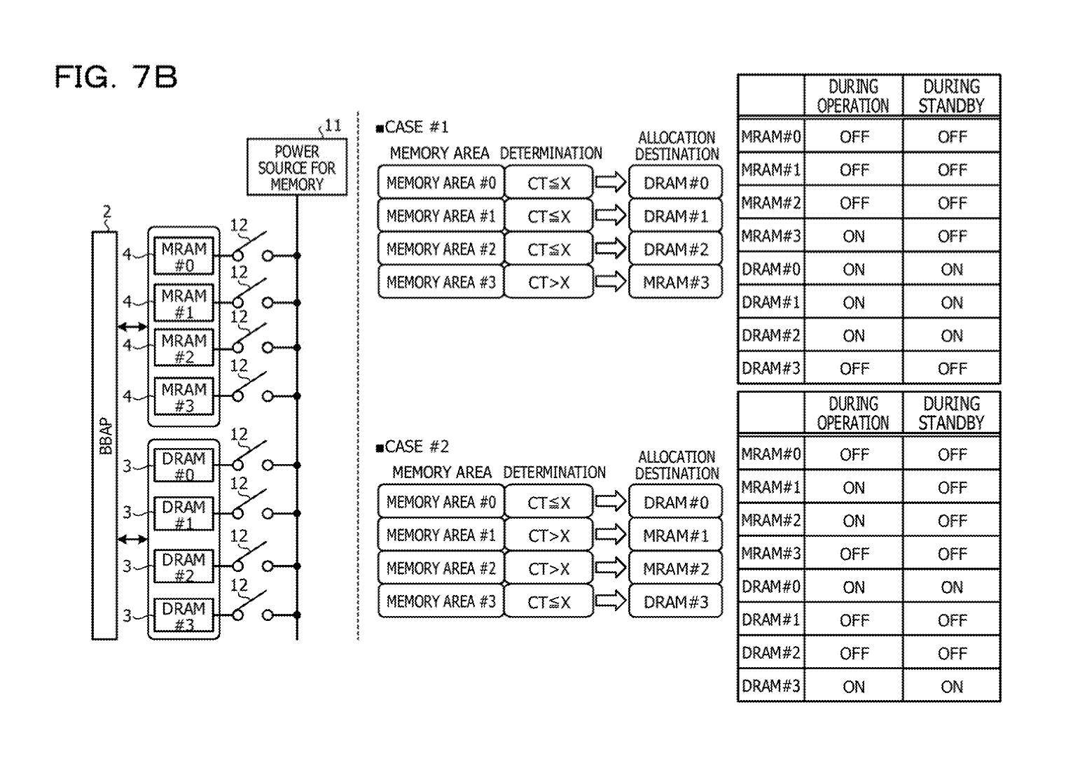

The power source setting unit 34 sets the power sources to the DRAM 3 and the MRAM 4 to be turned on or off using the switch 12 based on the instruction from the mode determination unit 33. FIG. 7A and FIG. 7B are diagrams for explaining turning on and off of the memory power source. FIG. 7A illustrates the case in which the number of the memory areas is one, and FIG. 7B illustrates the case in which the number of the memory areas is four.

As illustrated in FIG. 7A(a), when the DRAM is used, the power to the MRAM 4 is off during operation or during standby, and the power to the DRAM 3 is on during operation and during standby. Also, as illustrated in FIG. 7A(b), when the MRAM is used, the power to the MRAM 4 is on during operation, but is off during standby, and the power to the DRAM 3 is off both during operation and during standby.

Namely, the DRAM in use is powered on all the time, and the unused DRAM is powered off all the time. Also, the MRAM in use is powered on during operation, and is powered off during standby. The unused MRAM is powered off all the time.

Also, as illustrated in FIG. 7B, when there are multiple memory areas, the power is turned on and off for each memory area based on the powering on and off illustrated in FIG. 7A. In case #1, the DRAM 3 is used for the memory area #0 to the memory area #2, and the MRAM 4 is used for the memory area #3. In case #2, the DRAM 3 is used for the memory area #0 and the memory area #3, and the MRAM 4 is used for the memory area #1 and the memory area #2.

The swap unit 35 copies data of either one of the DRAM 3 or the MRAM 4 to the other based on an instruction from the mode determination unit 33. Namely, when the mode is changed from the DRAM use mode to the MRAM use mode, the swap unit 35 copies the data of the DRAM 3 to the MRAM 4, and when the mode is changed from the MRAM use mode to the DRAM use mode, the swap unit 35 copies the data of the MRAM 4 to the DRAM 3.

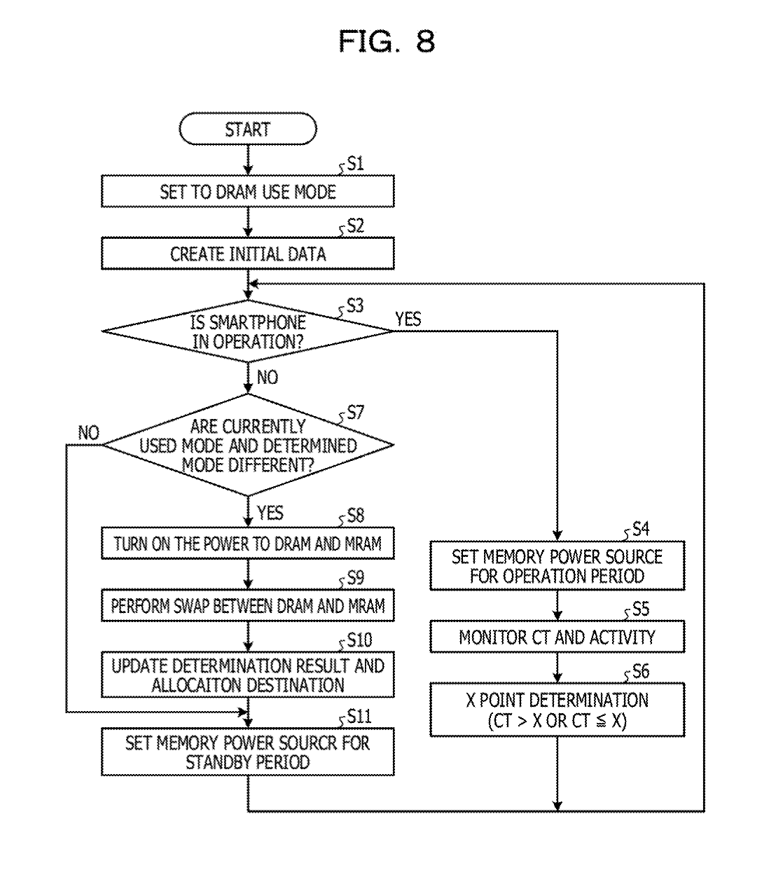

Next, a description will be given of the processing flow by the switching control unit 20. FIG. 8 is a flowchart illustrating the processing flow by the switching control unit 20. As illustrated in FIG. 8, when the smartphone 1 is started, the switching control unit 20 sets the mode to the DRAM use mode in the initialization processing (step S1), and creates the initial data of the activity, the operation period, and the standby period (step S2). The switching control unit 20 then writes the created initial data in the mode determination information storage unit 22.

The switching control unit 20 then determines whether or not the smartphone 1 is in operation (step S3). When the smartphone 1 is in operation, the switching control unit 20 performs the memory power source setting for operation period (step S4). In this regard, if the memory power source setting for the operation period is already set, nothing is performed. The switching control unit 20 then monitors the CT and the activity (step S5), and performs X-point determination (step S6). The switching control unit 20 then writes the determination result in the allocation information storage unit 21, and the processing returns to step S3.

When the smartphone 1 is not in operation, the switching control unit 20 determines whether or not the currently used mode and the determined mode are different (step S7). If they match, the processing proceeds to step S11. On the other hand, if the currently used mode and the determined mode are different, the switching control unit 20 turns on the power to the DRAM 3 and the MRAM 4 (step S8), and performs a swap between the DRAM 3 and the MRAM 4 (step S9). The switching control unit 20 then updates the determination result and the allocation destination in the allocation information storage unit 21 (step S10).

The switching control unit 20 then performs the memory power source setting for the standby period (step S11). In this regard, if the memory power source setting for the standby period has already been performed, nothing is performed. The processing of the switching control unit 20 returns to step S3.

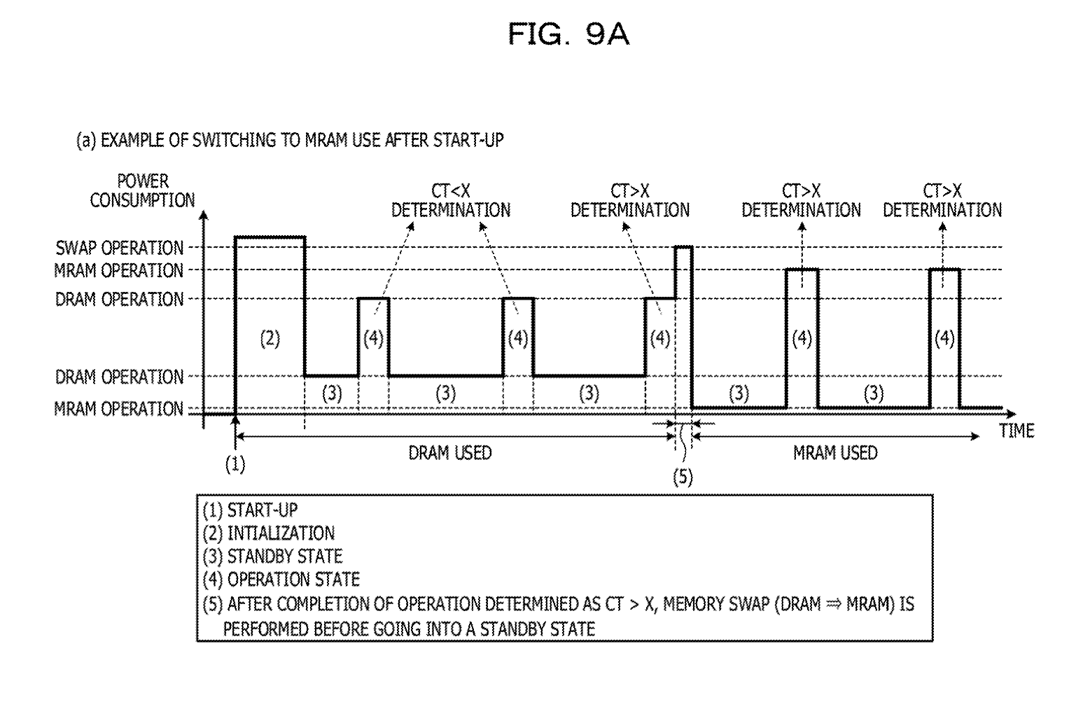

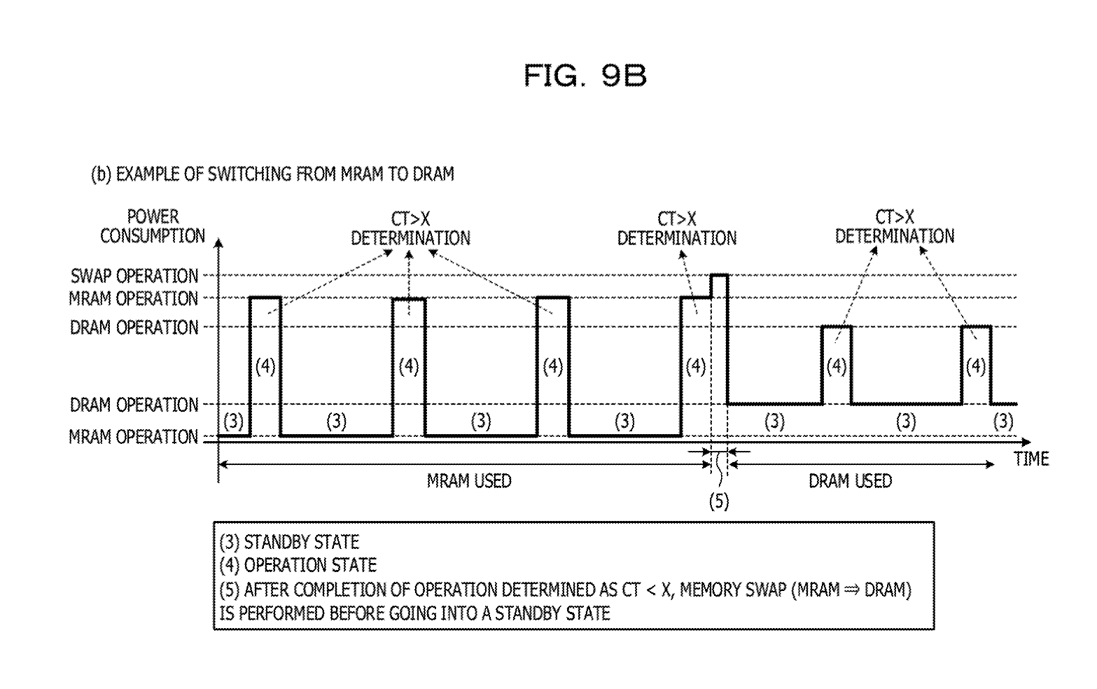

In this manner, the switching control unit 20 is capable of allocating the DRAM 3 or the MRAM 4 to the main memory in order to lower the power consumption of the smartphone 1, by monitoring the CT and the activity, and performing the X-point determination. In this regard, in FIG. 9, a description has been given of the processing flow in the case with one memory area. However, if there are multiple memory areas, the switching control unit 20 performs the processing in step S4 to step S10 for each memory area.

Next, a description will be given of an example of the switching operation. FIG. 9A and FIG. 9B are diagrams illustrating examples of the switching operation. FIG. 9A illustrates the switching from the DRAM 3 to the MRAM 4, and FIG. 9B illustrates the switching from the MRAM 4 to the DRAM 3. In FIG. 9A and FIG. 9B, the horizontal axis represents time, and the vertical axis represents the power consumption of the smartphone 1.

As illustrated in FIG. 9A, the smartphone 1 is started, and the power consumption starts to rise (1). The power consumption is heightened during the initialization (2). When the initialization is completed and the smartphone 1 goes into the standby state, the power consumption is lowered to the value corresponding to the DRAM standby (3). In the operation state, the power consumption rises to the value corresponding to the DRAM operation (4). When the smartphone 1 goes into the standby state, the power consumption is lowered to the value corresponding to the DRAM standby (3). In the following, while CT≦X, the DRAM 3 is used.

Then, when it is determined that CT>X in the operation state, a memory swap is performed from the DRAM 3 to the MRAM 4 before going into the standby state, and the power consumption rises to the value corresponding to the swap operation (5). In the standby state, the power consumption decreases to the value corresponding to the MRAM standby, which is lower than the DRAM standby (3). When the state goes into the operation state, the power consumption rises the value corresponding to the MRAM operation, which is higher than the DRAM operation (4). In the following, as long as CT>X, the MRAM 4 is used.

Then, as illustrated in FIG. 9B, if it is determined that CT<X in the operation state, a memory swap from the MRAM 4 to the DRAM 3 is performed before going into the standby state, and the power consumption rises to the value corresponding to the swap operation (5). When in the standby state, the power consumption falls to the value corresponding to the DRAM standby (3). When the state moves to the operation state, the power consumption rises to the value corresponding to the DRAM operation (4).

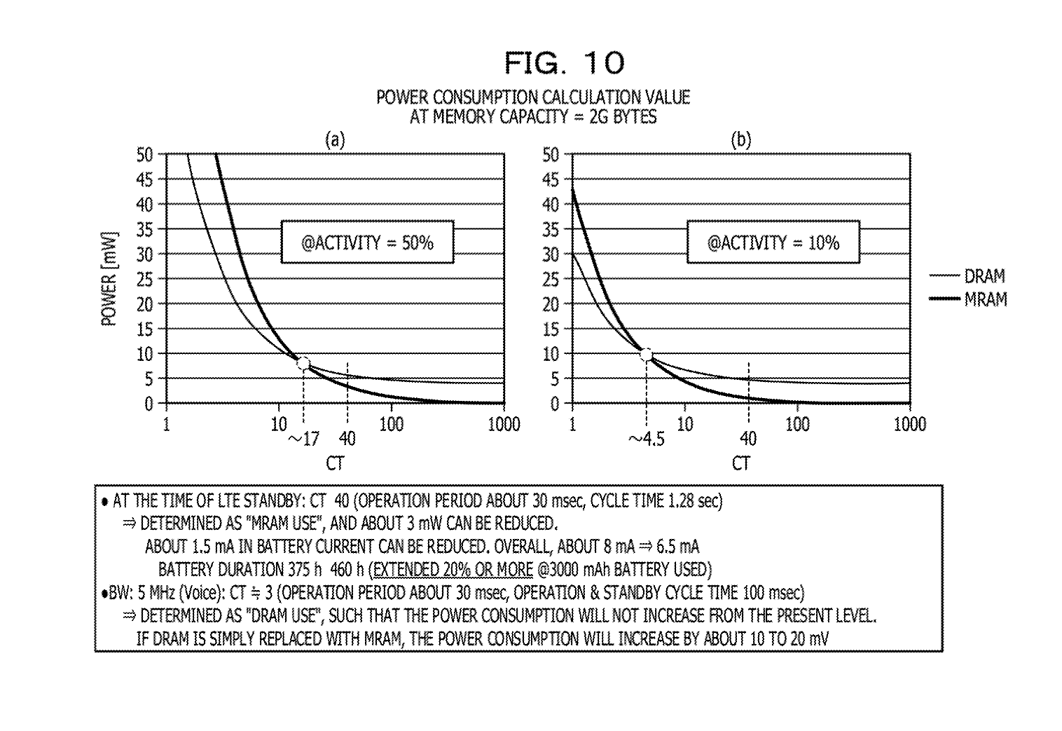

Next, a description will be given of advantageous effect of the switching control according to the first embodiment. FIG. 10 is a diagram illustrating advantageous effect of switching control according to the first embodiment. FIG. 10 illustrates the relationship between CT and the power consumption when the memory capacity is two gigabytes (G). Since the activity is considered to be 10% to 50%, the 50% activity case is illustrated in (a), and the 10% activity case is illustrated in (b). X is about 17 in the 50% activity case, and X is about 4.5 in the 10% activity case.

For example, during Long Term Evolution (LTE) standby state, the operation period is about 30 milliseconds (msec) and the cycle time is 1.28 sec, making CT about 40, which is larger than X. The switching control unit 20 thereby determines the MRAM 4 to be used enabling the power consumption lowered by about 3 milliwatts (mW). This corresponds to a reduction of 1.5 milliamperes (mA) for the battery current. Assuming the total current of about 8 milliamperes (mA), including the current for the processor, this is reduced to 6.5 mA, and in case of a 3000 milliampere-hour (mAh) battery, the battery duration is extended from 375 hours to 460 hours, longer by 20% or more.

Also, when a sound signal with a bandwidth (BW) of 5 megahertz (MHz) is processed, the operation period is about 30 msec and the cycle time is about 100 msec, making CT of about 3, which is smaller than X. The switching control unit 20 thereby determines the DRAM 3 to be used, thus no increase in the power consumption over the current level will result. Simply replacing the DRAM 3 with the MRAM 4 would have increased about 10 to 20 mW of power consumption.

As described above, in the first embodiment, the X-point determination unit 32 compares CT and X in order to determine which of the DRAM 3 or the MRAM 4 to use. Namely, the X-point determination unit 32 compares the amount of reduction in standby energy with the amount of increase in operation energy if the DRAM 3 is replaced with the MRAM 4, in order to determine which of the DRAM 3 or the MRAM 4 to use. The mode determination unit 33 then determines whether or not the currently used mode and the determination result by the X-point determination unit 32 match. If they do not match, the power source setting unit 34 and the swap unit 35 perform processing called for in a memory switching.

The switching control unit 20 is thereby enabled to perform memory switching such that the amount of reduction in standby energy becomes larger than the amount of increase in operation energy when the DRAM 3 is replaced with the MRAM 4. This thereby enabled the power consumption of the smartphone 1 to be lowered.

In addition, in the first embodiment, the X-point determination unit 32 determines which of the DRAM 3 or the MRAM 4 to use based on the activity and CT. This enables the switching control unit 20 to control memory switching by monitoring the activity and CT.

In addition, in the first embodiment, when the MRAM 4 is used, the power source setting unit 34 turns off the power to the MRAM 4 in the standby state. This enables the switching control unit 20 to lower the power consumption of the smartphone 1.

Further, in the first embodiment, the switching control unit 20 performs memory switching at the time the operation state changes to the standby state, thereby enabling the influence to the operation of the smartphone 1 to be reduced.

### Second Embodiment

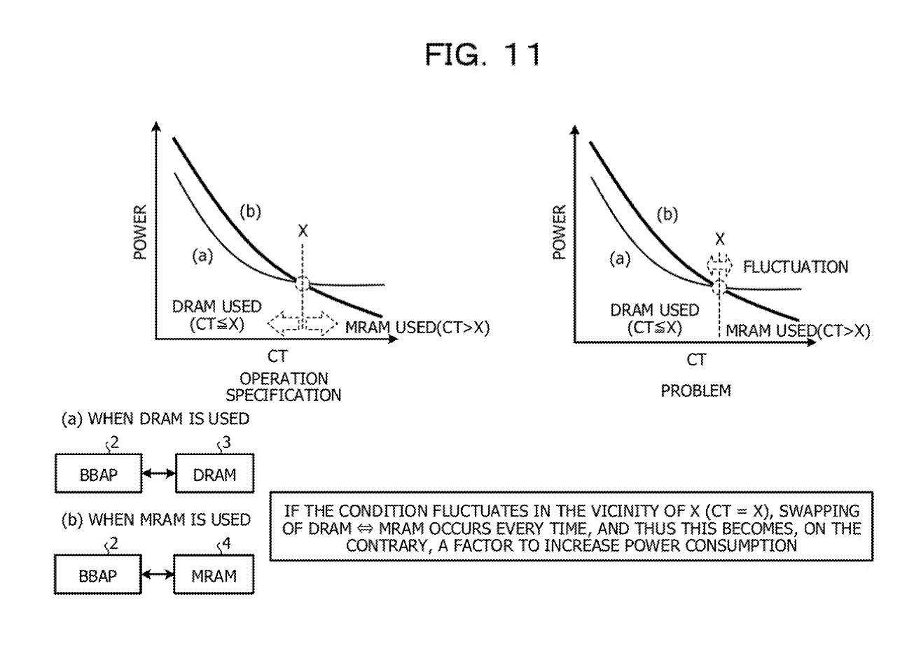

In the above-described first embodiment, a description has been given of the case in which the DRAM 3 is used when CT≦X, and the MRAM 4 is used when CT>X. However, if CT fluctuates in the vicinity of X, switching between the DRAM 3 and the MRAM 4 occurs frequently. FIG. 11 is a diagram for explaining the case in which CT fluctuates in the vicinity of X. As illustrated in FIG. 11, if CT fluctuates in the vicinity of X, a change from CT≦X to CT>X and a change from CT>X to CT≦X frequently occur, and thus swapping between the DRAM 3 and the MRAM 4 frequently occurs. As a result, the power consumption, on the contrary, increases by the swapping. Thus, in a second embodiment, a description will be given of switching control that avoids an increase in the power consumption even if CT fluctuates in the vicinity of X.

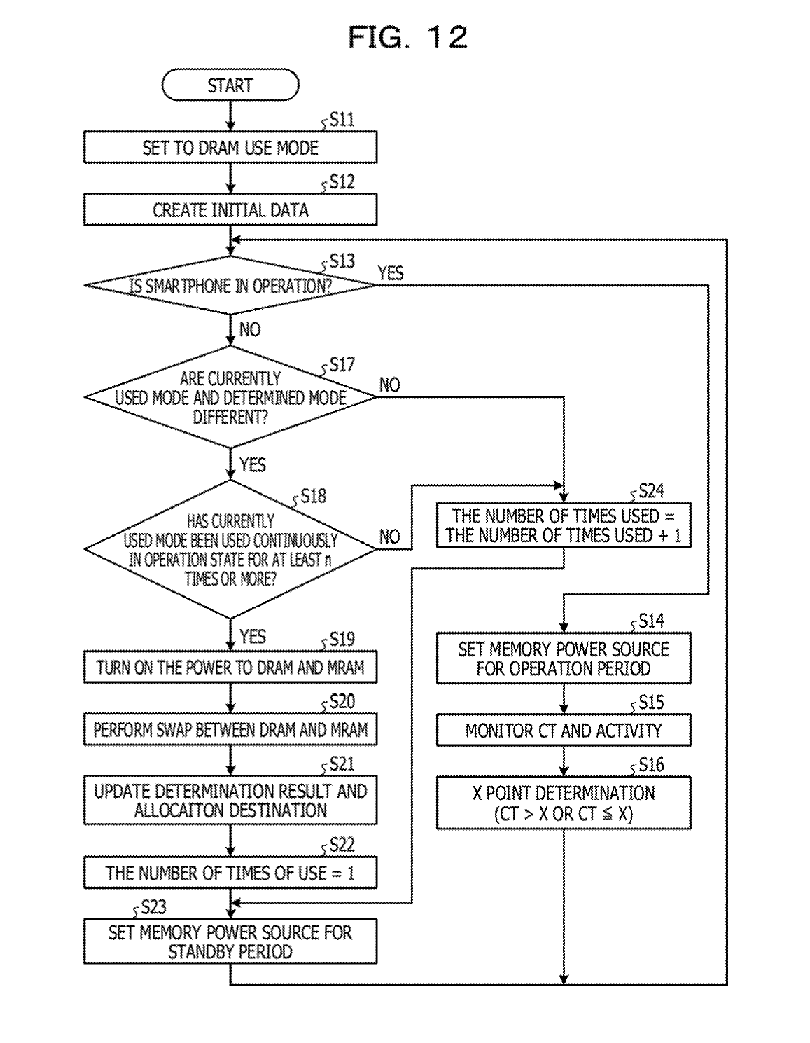

FIG. 12 is a flowchart illustrating the processing flow by the switching control unit 20 according to the second embodiment. As illustrated in FIG. 12, when the smartphone 1 is started, the switching control unit 20 sets the mode to the DRAM use mode in the initialization processing (step S11), and creates the initial data of the activity, the operation period, the standby period, and the number of times used (step S12).

Here, the number of times used indicates the number of times the same main memory use mode has been used in a row. The switching control unit 20 then writes the created initial data in the mode determination information storage unit 22. In this regard, the number of times of used is stored for each memory area in the mode determination information storage unit 22.

The switching control unit 20 then determines whether or not the smartphone 1 is in operation (step S13). If the smartphone 1 is in operation, the switching control unit 20 performs the memory power source setting for the operation period (step S14). The switching control unit 20 then monitors CT and the activity (step S15), and performs the X-point determination (step S16). The switching control unit 20 then writes the determination result in the allocation information storage unit 21, and the processing returns to step S13.

On the other hand, if the smartphone 1 is not in operation, the switching control unit 20 determines whether or not the currently used mode and the determined mode are different (step S17). Then, if they are different, the switching control unit 20 determines whether or not the currently used mode has been continuously used at least n times or more in the operation state (step S18). Here, n is a positive integer that indicates a threshold value of the number of times in which the currently used mode is to be continuously used.

If the currently used mode has been used at least n times or more in the operation state, the switching control unit 20 turns on the power to the DRAM 3 and the MRAM 4 (step S19), and performs a swap between the DRAM 3 and the MRAM 4 (step S20). The switching control unit 20 then updates the determination result and the allocation destination in the allocation information storage unit 21 (step S21), and initializes the number of times used to 1 (step S22). The switching control unit 20 then performs the memory power source setting for the standby period (step S23), and the processing returns to step S13.

In addition, if the number of continuous use in the operation state in the currently used mode is less than n times (step S18, No), or the currently used mode matches the determined mode (step S17, No), the switching control unit 20 adds 1 to the number of times used (step S24), and the processing proceeds to step S23.

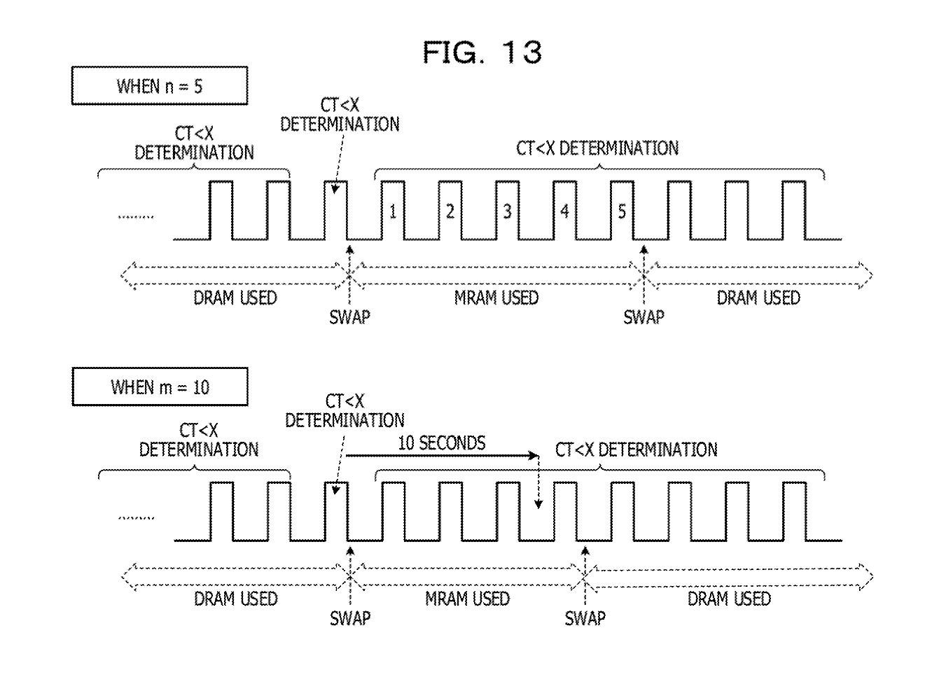

FIG. 13 is a diagram illustrating an example of the switching operation according to the second embodiment. As illustrated in FIG. 13, when n=5, the state changes from CT<X to CT>X and swapping is performed. Even if, after switching from the DRAM 3 to the MRAM 4 is performed, the state changes again to CT<X, switching to the DRAM 3 is not performed until the MRAM 4 is used continuously for five times in the operation state.

Furthermore, in place of the number of times n of the continuous operation state, the number of seconds m after swapping may be used. In FIG. 13, when m=10, the state changes from CT<X to CT>X, and the swapping is performed. If the state changes to CT<X after switching from the DRAM 3 to the MRAM 4, switching to the DRAM 3 is not performed for the period of 10 seconds after the swapping.

As described above, in the second embodiment, the switching control unit 20 is enabled to avoid an increase in the power consumption when CT fluctuates in the vicinity of X, by performing control such that switching between the DRAM 3 and the MRAM 4 is suppressed until the currently used mode is used continuously at least n times or more in the operation state.

### Third Embodiment

In place of the number of times n of the continuous operation state or the number of seconds m after swapping, it is possible to avoid an increase in the power consumption by a hysteresis determination method when CT fluctuates in the vicinity of X. Thus in a third embodiment, a description will be given of the case in which an increase in the power consumption when CT fluctuates in the vicinity of X is avoided by the hysteresis determination method.

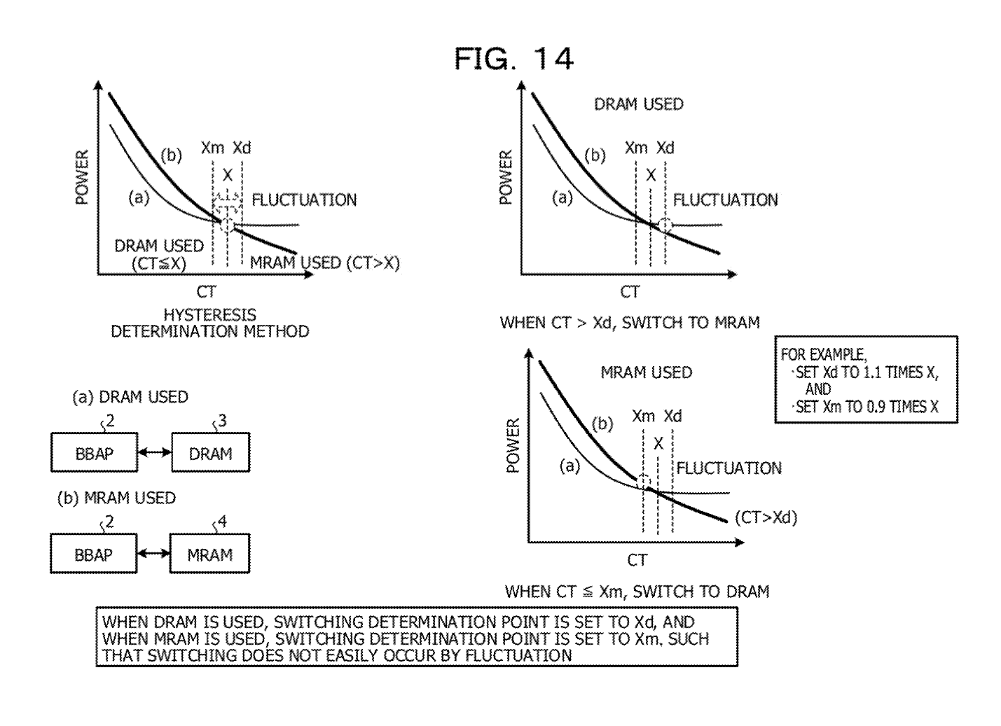

FIG. 14 is a diagram for explaining switching control by a hysteresis determination method. As illustrated in FIG. 14, in the hysteresis determination method, in place of X as the threshold value of CT, two threshold values, namely Xm, which is smaller than X, and Xd, which is larger than X, are used. Xm is a threshold value for switching from the MRAM 4 to the DRAM 3, and Xd is a threshold value for switching from the DRAM 3 to the MRAM 4.

Namely, when CT>Xd, the switching control unit 20 performs switching to the MRAM 4, and when CT≦Xm, the switching control unit 20 performs switching to the DRAM 3. For example, Xd is 1.1 times X, and Xm is 0.9 times X.

In this manner, by applying the switching determination point Xd>X when the DRAM is used and applying the switching determination point Xm<X when the MRAM is used, the switching control unit 20 is capable of exerting control such that the switching does not easily occur by the fluctuation of CT.

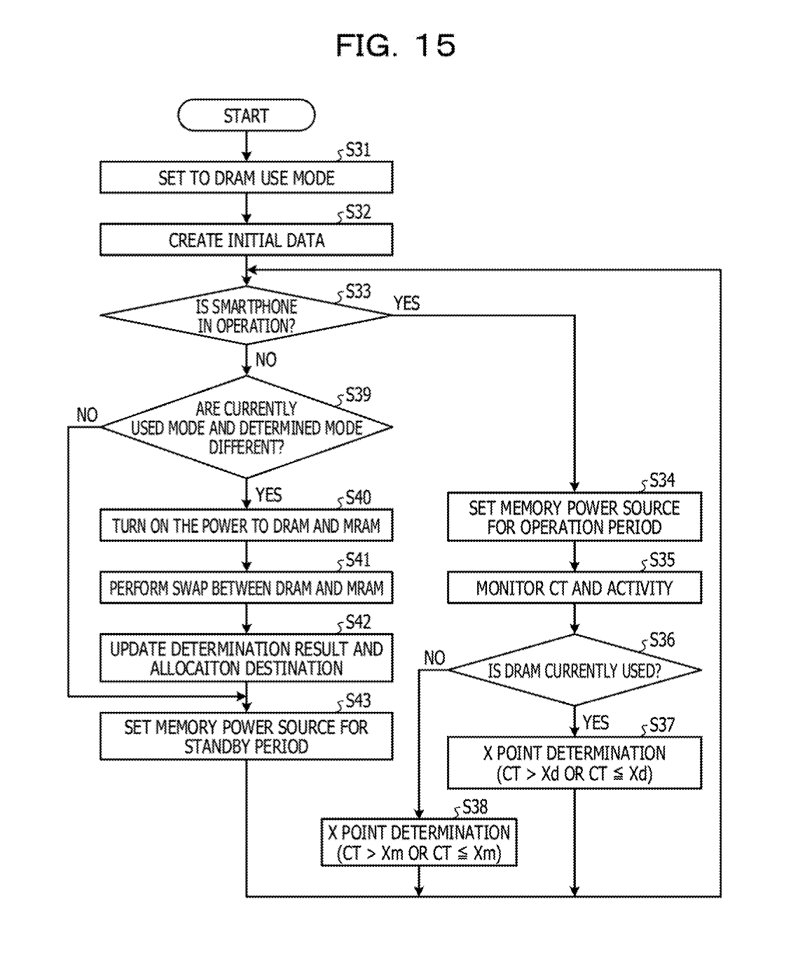

FIG. 15 is a flowchart illustrating the processing flow by the switching control unit 20 according to the third embodiment. As illustrated in FIG. 15, when the smartphone 1 is started, the switching control unit 20 sets the mode to the DRAM use mode in the initialization processing (step S31), and creates the initial data of the activity, the operation period, and the standby period (step S32). The switching control unit 20 then writes the created initial data in the mode determination information storage unit 22.

The switching control unit 20 then determines whether or not the smartphone 1 is in operation (step S33). When the smartphone 1 is in operation, the switching control unit 20 performs the memory power source setting for operation period (step S34). The switching control unit 20 then monitors CT and the activity (step S35).

The switching control unit 20 then determines whether or not the DRAM 3 is currently used (step S36). If the DRAM 3 is currently used, the switching control unit 20 performs the X-point determination using Xd (step S37). On the other hand, if the MRAM 4 is currently used, the switching control unit 20 performs the X-point determination using Xm (step S38). Then the switching control unit 20 writes the determination result in the allocation information storage unit 21, and the processing returns to step S33.

On the other hand, if the smartphone 1 is not in operation, the switching control unit 20 determines whether or not the currently used mode and the determined mode are different (step S39). If they match, the processing proceeds to step S43. On the other hand, if the currently used mode and the determined mode are different, the switching control unit 20 turns on the power to the DRAM 3 and the MRAM 4 (step S40), and performs a swap between the DRAM 3 and the MRAM 4 (step S41). The switching control unit 20 then updates the determination result and the allocation destination in the allocation information storage unit 21 (step S42). The switching control unit 20 then performs the memory power source setting for the standby period (step S43), and the processing returns to step S33.

As described above, in the third embodiment, the switching control unit 20 performs the switching control by the hysteresis determination method. This enables the switching control unit 20 to avoid the increase in the power consumption when the CT fluctuates in the vicinity of X.

Note that, in the first to the third embodiments, descriptions have been given of the smartphone 1. However, the present disclosure is not limited thereto. For example, it is possible to apply the present disclosure to the other information processing apparatuses, such as a wearable device, and the like, in the same manner.

Also, in the first to the third embodiments, the descriptions have been given of the case in which the smartphone 1 includes the DRAM 3 and the MRAM 4. However, the present disclosure is not limited thereto. It is possible to apply the present disclosure to the case in which another volatile memory is included in place of the DRAM 3, or the case in which another nonvolatile memory is included in place of the MRAM 4, in the same manner.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An information processing apparatus comprising:
a volatile memory;
a nonvolatile memory; and
a processor coupled to the volatile memory and the nonvolatile memory, the processor configured to:
make a selection of the volatile memory or the nonvolatile memory to supply power, based on a first difference between power consumption of the volatile memory and power consumption of the nonvolatile memory during standby, and a second difference between power consumption of the volatile memory and power consumption of the nonvolatile memory during an operation state, and
switch between the volatile memory and the nonvolatile memory to supply power on the basis of the selection and whether the volatile memory or the nonvolatile memory being used currently by the processor.

2. The information processing apparatus according to claim 1,
wherein the processor selects to use either of the volatile memory or the nonvolatile memory by comparison of the first difference and the second difference based on a memory operation rate in an operation state, and a ratio of operation period to standby period or a ratio of operation period to cycle time.

3. The information processing apparatus according to claim 1,
wherein when the processor selects the volatile memory, the processor controls the volatile memory to turn on and the nonvolatile memory to turn off, and when the processor selects the nonvolatile memory, the processor controls the volatile memory to turn off and when the nonvolatile memory is in an operation state, the nonvolatile memory to turn on and when the nonvolatile memory is in a standby state, the nonvolatile memory to turn off.

4. The information processing apparatus according to claim 1,
wherein the processor selects the volatile memory or the nonvolatile memory during the operation state, and
when a state is changed from the operation state to the standby state, the processor switches the use of the volatile memory and the nonvolatile memory.

5. The information processing apparatus according to claim 1,
wherein the processor does not switch the memories to use for a predetermined number of times or for a predetermined duration after the processor switches the memories to use.

6. The information processing apparatus according to claim 2,
wherein a first threshold value of the ratios when the processor uses the volatile memory is different from a second threshold value of the ratios when the processor uses the nonvolatile memory.

7. A switching control method for an information processing apparatus including a volatile memory and a nonvolatile memory and a processor coupled to the volatile memory and the nonvolatile memory, comprising:
making a selection of the volatile memory or the nonvolatile memory to be supplied power, based on a first difference between power consumption of the volatile memory and power consumption of the nonvolatile memory during standby, and a second difference between power consumption of the volatile memory and power consumption of the nonvolatile memory during an operation state, and
switching between the volatile memory and the nonvolatile memory to be supplied power on the basis of the selection and whether the volatile memory or the nonvolatile memory being used currently by the processor.
